(19) United States
(12) Patent Application Publication
(10) Pub. No.: US 2010/0319767 A1
(43) Pub. Date: Dec. 23, 2010

(54) METHOD FOR PROVIDING A CONTACT ON THE BACK SURFACE OF A SOLAR CELL, AND A SOLAR CELL WITH CONTACTS PROVIDED ACCORDING TO THE METHOD

(75) Inventor: Erik Sauar, Oslo (NO)

Correspondence Address: BIRCH STEWART KOLASCH & BIRCH, PO BOX 747, FALLS CHURCH, VA, 22040-0747, US

(73) Assignee: RENEWABLE ENERGY CORPORATION ASA, SANDVIKA (NO)

(21) Appl. No.: 12/671,325

(22) PCT Filed: Jul. 25, 2008
(86) PCT No.: PCT/NO2008/000278

§ 371 Date: Jul. 27, 2010

Related U.S. Application Data
(60) Provisional application No. 60/952,870, filed on Jul. 31, 2007.

(30) Foreign Application Priority Data
Jul. 31, 2007 (GB) 0714980.0

(51) Int. Cl. H01L 31/04; H01L 31/18

(52) U.S. Cl. 136/256; 438/72; 438/98

(57) ABSTRACT

The present invention relates to a solar cell which includes a silicon layer (1), and a method for providing a contact on the back surface of such a solar cell. The method comprises the following steps: a) adding a passivation layer (2) over the back surface of the silicon layer (1); b) adding a plating seed layer (4) over the passivation layer (2); c) separating the plating seed layer (4) by a first area (A) into first and second electrode areas; d) opening a second area (B) of the plating seed layer (4); e) opening the second area (B) of the passivation layer (2); f) applying a contact plating (3) to the opening of the second area (B) of the passivation layer (2) as well as to the plating seed layer (4) surrounding the second area (B).

In the context of the present application the expression “solar cell” refers to a device comprising a silicon substrate as e.g. a wafer or a thin film.

### FIELD OF THE INVENTION

The present invention relates to a method for providing a contact on the back surface of a solar cell. The invention also relates to a solar cell with contacts provided according to the method.

### BACKGROUND OF THE INVENTION

The conventional back contacted solar cell is illustrated in FIG. 1. The conventional process is to apply a plating 3 onto the crystalline silicon 1 in an opening of a plating barrier 2. Normally the plating barrier 2 is also the surface passivation and/or anti reflective coating layer.

The prior art requires the plated contacts to be relatively thick to carry the required current in such back contacted solar cells. Since the plated metal has a thermal expansion coefficient different from silicon, a resulting problem is that the plating may fall off when exposed to variations in temperature. Another drawback with this design of the contacts is that the metal/Si interface area must be relatively large to provide the plating process with a surface big enough to form the required cross sectional area of the contacts in short enough processing times for mass production. A large metal/Si contact area will increase surface recombination and, in turn, reduce the efficiency of the solar cell. Finally, the long time required to plate a thick layer implies a need for large investments in manufacturing equipment for high volume manufacturing.

A design of back contacts that allows for both small contact areas and large cross sectional areas on the conductors have been disclosed in US published patent application 2004/0200520 A1. The procedure to manufacture such a solar cell is however complex and therefore difficult to realize at a competitive cost.

An object of the present invention is to provide a cost-effective method using plating for providing electrical contacts on back contacted solar cells. The method further allows for a small metal/Si contact interface in combination with a large enough cross sectional area of the contacts to carry the current generated by the solar cell. The method is fully applicable, however, also to the back contact of a solar cell with both front and back contacts.

### SUMMARY OF THE INVENTION

The present invention is defined in the enclosed independent claims. Further embodiments of the invention are defined in the dependent claims.

### BRIEF DESCRIPTION OF THE DRAWINGS

Embodiments of the invention will be described in detail below, with reference to the enclosed drawings, where:

FIG. 1 illustrates the plating of a back contacted solar cell according to the prior art.

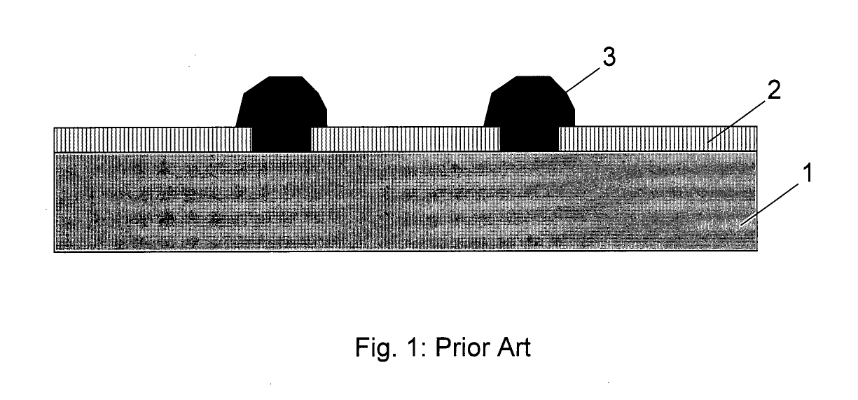

FIG. 2 illustrates the plating of a back contacted solar cell according to an embodiment of the invention.

FIG. 3a-e illustrates a first embodiment of the method according to the invention.

FIG. 4a-d illustrates a second embodiment of the method according to the invention.

FIG. 5a-d illustrates a third embodiment of the method according to the invention.

FIG. 6a-f illustrates a sixth embodiment of the method according to the invention.

FIG. 7a-e illustrates a seventh embodiment of the method according to the invention.

### DETAILED DESCRIPTION

Embodiments of the method and the solar cell according to the invention will be described in detail below. It should however be noted that the invention is not limited to these embodiments, but can be varied within the scope of the claims below. It should also be noted that elements of some of the embodiments may readily be combined with elements of other embodiments.

### First Embodiment

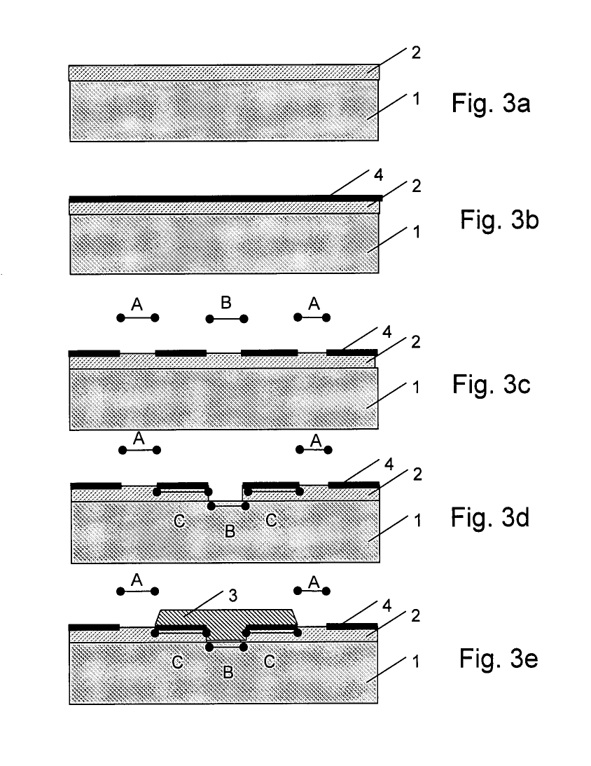

A first embodiment of the method will now be described with reference to FIG. 3a-e.

In a first step (illustrated in FIG. 3a) a passivation stack or passivation layer 2 is applied to a silicon wafer 1. The passivation layer 2 can for example comprise a-Si and SiNx or SiOx and/or SiNx etc.

In a second step (illustrated in FIG. 3b), a plating seed layer 4 is applied over the complete surface of the passivation layer 2. The plating seed layer 4 can for example comprise silver, nickel, copper, a-Si or micro-Si etc.

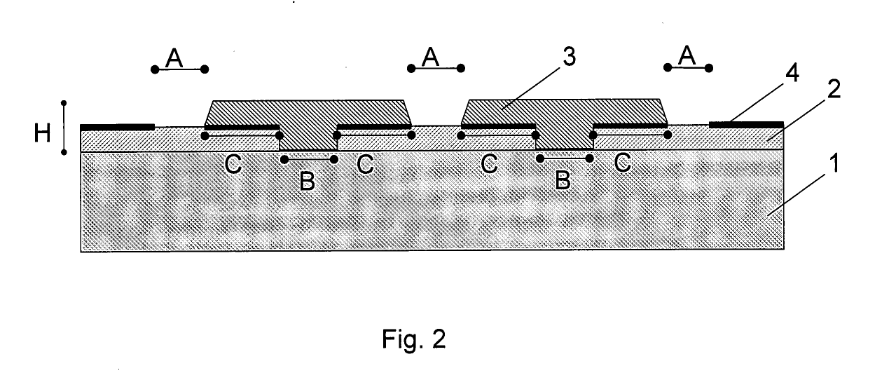

In a third step, an etching agent is applied to split the plating seed layer 4 into + and − areas, i.e. the plating seed layer is opened in first areas denoted A. In the same process step, the plating seed layer 4 in the area denoted B in FIG. 2 is also opened (result illustrated in FIG. 3c). The etching agent can for example be KOH for Si based materials; acids can be used for etching away silver, nickel and other metals.

In a next step, the passivation layer 2 is opened to provide space for the solar cell conductors 3 (illustrated in FIG. 3d). In FIG. 2, the open areas of the passivation layer 2 are denoted with the letter B. The contact opening can for example be achieved by applying an etch-resist over the complete backside of the cell with the exception of the areas B where the contact shall be formed. Another option is to apply an etch resist only to the openings A in FIG. 2 provided that the plating seed layer as applied in step two above is resistant to the etching agent used for opening the passivation layer (A).

Thereafter the cell is exposed to an etching liquid and the passivation layer gets etched away so that the silicon 1 of area B gets exposed.

The etch resist is then removed.

The etch resist is an agent which adheres to the materials of the cell, but which protects the materials from the etching agent during the etching process.

Yet another alternative to remove the passivation layer in B is by directly applying an etching-agent e.g. via ink-jet to the areas B.

As can bee seen in FIG. 2, there is, as a consequence, an area C between area A and area B where the plating seed layer 4 is not removed.

In a next step (illustrated in FIG. 3e), the contact plating 3 is applied to the complete back side of the solar cell, except for the opening areas A. That is, the contact plating 3 is covering areas B and C in FIG. 2. The contact plating can for example comprise a nickel seed and a barrier layer, then copper and/or silver as main charge carriers followed by silver, tin or other suitable material for solderability purposes.

As seen in FIG. 2 and FIG. 3c, the contact plating 3 has a substantially T-shaped cross sectional form.

### Second Embodiment

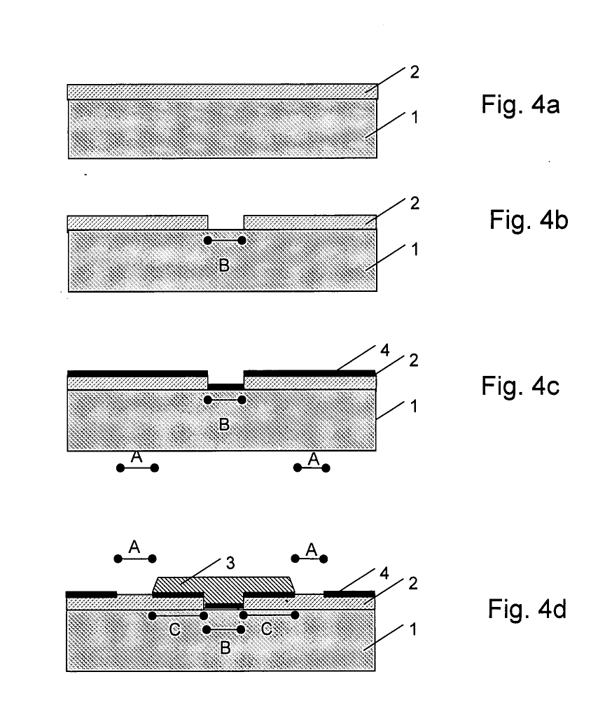

A second embodiment will be described with reference to FIG. 4a-d.

In the first step (illustrated in FIG. 4a), a passivation stack or passivation layer 2 is applied to a silicon wafer 1. The passivation layer 2 can for example comprise a-Si and SiNx or SiOx and/or SiNx etc.

In a second step, the passivation layer 2 is opened to provide space for a contact plating 3. As described in the first embodiment, the contact plating 3 forms the electrical contact of the solar cell. In FIG. 2, the open areas of the passivation layer 2 are denoted with the letter B (illustrated in FIG. 4b).

In a third step, a plating seed layer 4 is applied over the complete surface of the cell (illustrated in FIG. 4c). The appliance is performed by spraying, printing or evaporating a-Si and/or a metal, such as nickel and/or silver over the surface of the cell.

In a fourth step, the plating seed layer 4 is opened by means of applying an etch-resist to the entire backside of the solar cell, except for the areas denoted A in FIG. 2, followed by exposing the solar cell to an etching agent. This will remove the plating seed layer 4 from the area A and hence split the plating seed layer 4 into + and − areas.

In a fifth step, the contact plating 3 is applied to the complete back side of the solar cell, except for the opening areas A. That is, the contact plating 3 is covering areas B and C in FIG. 2. The contact plating can for example comprise a palladium and/or nickel seed and barrier layer, then copper and/or silver etc (fourth and fifth step illustrated in FIG. 4d).

### Third Embodiment

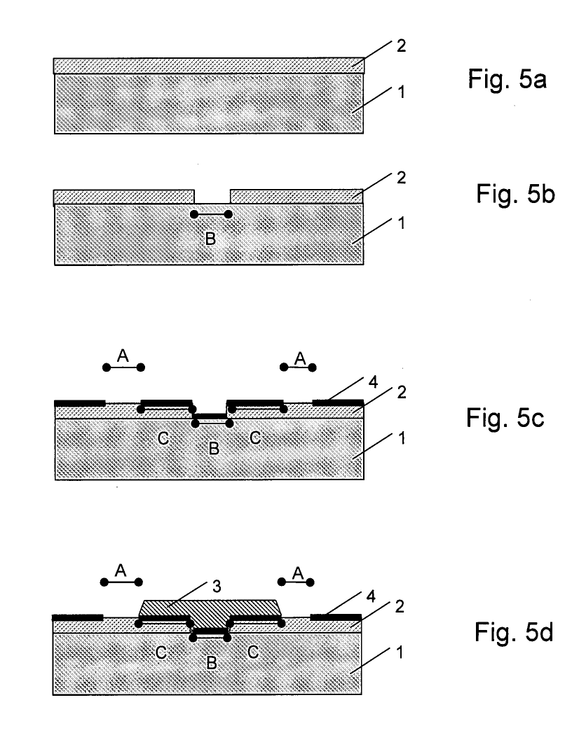

A third embodiment will be described with reference to FIG. 5a-d.

In the third embodiment, the plating seed layer 4 is applied after the opening of area B as described in the second embodiment (illustrated in FIG. 5b), but it is applied in a patterned way without covering the complete surface, e.g. the plating seed layer 4 is only applied to the areas C and B, but not onto areas A (illustrated in FIG. 5c). Such plating seed layer application can for example be made by ink-jet printing the plating seed layer 4 in a predetermined pattern utilizing inks containing for example palladium, silver or nickel.

Thereafter, the contact plating 3 is applied in the same way as described in the second embodiment (illustrated in FIG. 5d).

### Fourth Embodiment

In a fourth embodiment, the etching agent for opening of the passivation layer 2 and/or the plating seed layer is applied only in selected areas by means of e.g. ink-jetting. Consequently, it would not be necessary to apply an etch-resist to protect certain areas before the etching process.

### Fifth Embodiment

In a fifth embodiment, a laser is used to provide the openings in the plating seed layer 4 and/or the passivation layer 2. A requirement for this is that the materials chosen for the layers 2 and 4 are of a type that can be removed with laser.

### Sixth Embodiment

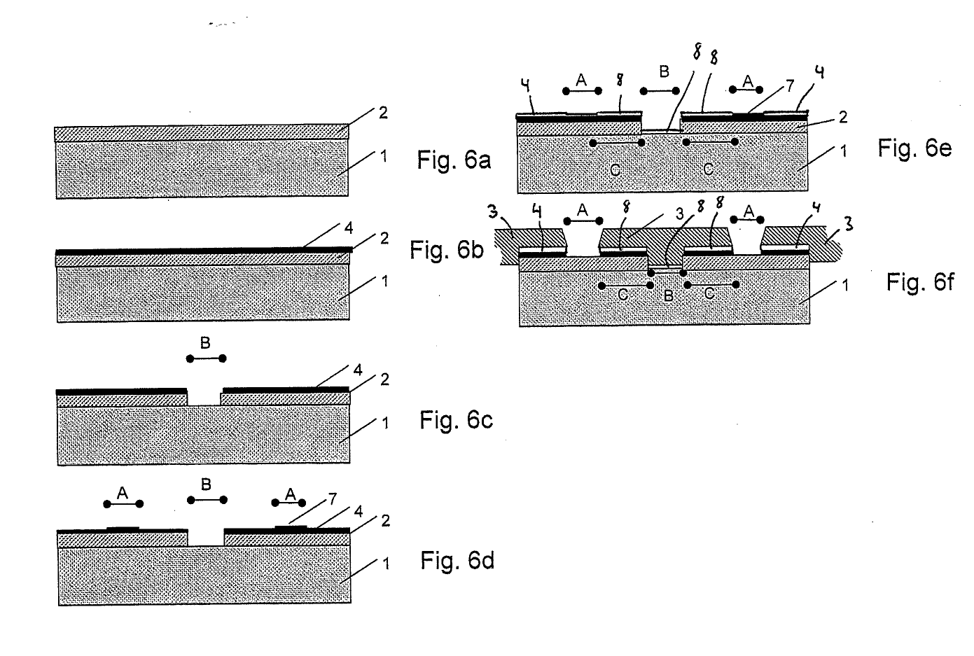

In a sixth embodiment (illustrated in FIG. 6a-f), the plating seed layer 4 consists of for example a-Si as described in embodiment 1. The openings B are provided by means of e.g. laser ablation. A plating resist layer 7 is then deposited on the areas A by means of e.g. inkjet. A metal barrier layer 8 e.g. nickel, nickel-phosphorous or tungsten is then deposited by plating on areas B and C (illustrated schematically in FIG. 6e). The plating resist layer 7 in areas A is then removed by means of an etching agent, which also will remove the plating seed layer 4 in areas A. In a next step, a thicker metal layer of for example copper or silver for providing the contact plating 3 is deposited by means of plating on top of the plating barrier layer in area B and C. Alternatively, the plating resist layer 7 can be removed after the application of the contact plating 3.

### Seventh Embodiment

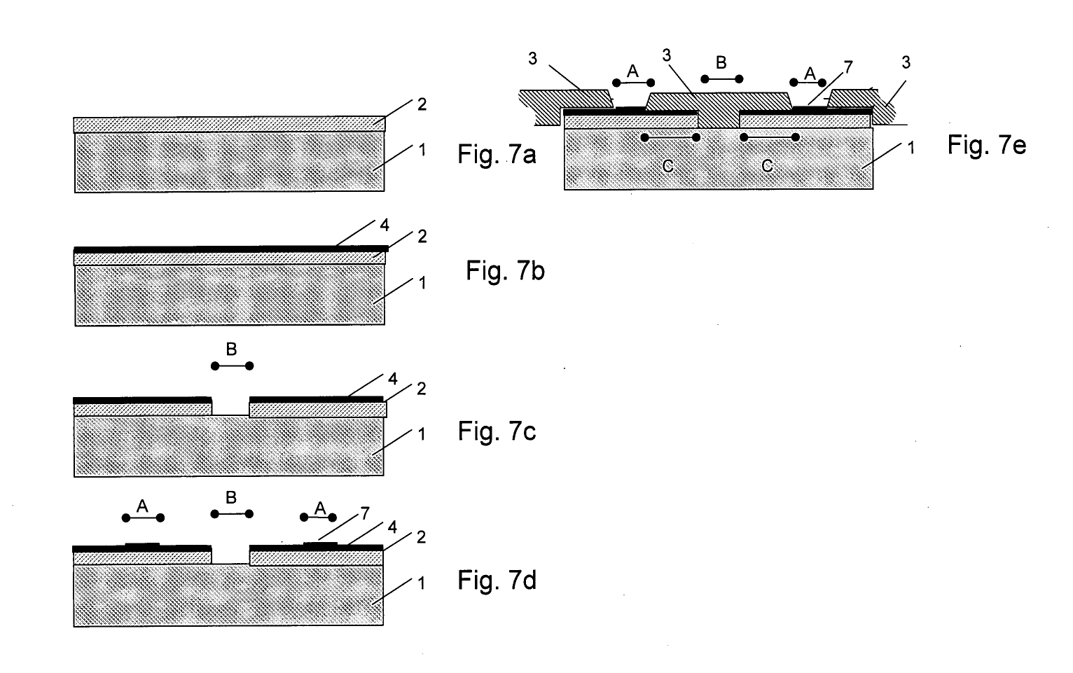

In a seventh embodiment (illustrated in FIG. 7a-e), the plating seed layer 4 consists of for example a-Si as described in embodiment 1. The passivation layer and plating seed layer is then opened in area B. Alternatively, the plating seed layer could be deposited after opening of the passivation stack in area B, as described in embodiment 3. A plating resist layer 7 is then deposited on the areas A by means of e.g. inkjet or dispensing, as illustrated in FIG. 7d. The plating resist should preferably be a reflective layer and could e.g. be made up of one or more of the following materials: polyamide, sulfo-polyester, polyketone, polyester, and acrylic resins, and where the materials have been made reflective by loading them with a white pigment such as sub-micrometer particles of titanium dioxide.

A metal seed and barrier layer, e.g. nickel or nickel-phosphorous, is then deposited by plating on areas B and C (illustrated schematically in FIG. 7e). In a next step, a thicker metal layer of for example copper or silver for building up the desired thickness of metal in the contacts 3 is deposited by means of plating on top of the plating seed and barrier layer in area B and C.

In FIG. 7e it has been shown that contact platings 3 for neighbouring contacts are provided.

### Common Features

FIG. 2 illustrates a solar cell which comprises a photovoltaic absorber material layer, such as a silicon layer 1. The solar cell further comprises a back surface of the solar cell, illustrated as the upper surface, and a front surface of the solar cell, illustrated as the lower surface. At least one contact 3 (two contacts are illustrated in FIG. 2) is provided on the back surface. The at least one contact 3 has been provided on the back surface of the solar cell by the steps of

a) adding a passivation layer or a stack of passivation layers 2 over the back surface of the silicon layer 1;
b) adding a plating seed layer 4 over the passivation layer 2;
c) separating the plating seed layer 4 by a first area A into first and second electrode areas;
d) opening a second area B of the plating seed layer 4;
e) opening the second area B of the passivation layer 2; and
f) applying a contact plating 3 to the opening of the second area B of the passivation layer 2 as well as to the plating seed layer 4 surrounding the second area B.

In an aspect, step c) of separating the plating seed layer 4 by a first area A into first and second electrode areas may comprise opening said area A of the plating seed layer 4. More specifically, step c) may be performed by first applying an etch-resistant agent to the solar cell in areas except from the first area A and thereafter applying an etching agent to etch the plating seed layer 4 open in the first area A.

In an alternative aspect, step c) comprises applying an insulating material on the plating seed layer. More specifically, in this aspect step c) may comprise depositing a plating resist layer to the solar cell in the first area A, or alternatively, a reflective plating resist is deposited on the passivation layer.

In any of the above two aspects, steps c) and d) may be performed simultaneously.

In an aspect, step e) may be performed before step b). Alternatively, step b) may be performed after step e).

In an aspect, step e) may be performed by first applying an etch-resistant agent to the solar cell in areas except from the second area B and thereafter a applying an etching agent to etch the passivation layer 2 open in the second area B.

In an aspect, at least one of the steps c), d) or e) may comprise applying an etching agent directly to the second area B. In another aspect, at least one of the steps c), d) or e) may comprise a laser ablation process.

The contact plating 3 may have a substantially T-shaped cross sectional form. Contact plating 3 may also be provided for neighbouring contacts in all embodiments, although this has been specifically illustrated by example only for the seventh embodiment (FIG. 7e).

According to the embodiments described above, it is provided a solar cell with an increased area for plating electrical conductors on solar cells. This increased area is constituted by the contact area B (indicates the area where the silicon layer 1 is in contact with the contact plating 3) plus plating area C×2 (indicating the area C on each side of area B where the contact plating 3 is fastened to the plating seed layer 2).

Moreover, the plating area (2×C) may be larger than the contact area B, thereby reducing the plating thickness H.

It should be noted that the plating seed layer 4 can comprise a reflective material in order to enhance light trapping in the solar cell.

The desired electrical performance of the solar cell is dependent on that ohmic contact is established between the metal contacts and base material (silicon). An ohmic contact can for instance be created by a heat treatment for either creating a silicide or an eutectic phase. The heat treatment could either be done after depositing the first metal contact and barrier layer, or after deposition of the whole metal stack. The heat treatment could for example be done in a conveyorized oven system or by locally heating the contact areas (B) with a laser.

In an alternative process, a thin layer, or, alternatively, nanometer-sized nucleis, of palladium is deposited on the wafer before an electroless deposited seed and barrier layer. Palladium enhances nucleation for electroless plating chemistries, resulting in more conformal metal coatings. In addition, the thermal budget for creating a silicide is low for palladium compared to most of the commonly used transition metal silicides for making ohmic contacts on silicon.

A useful result is that back contacted solar cells can be made more robust towards temperature cycling, hence allowing cell designs with higher currents per electrical contact than in conventional plated electrical contacts. This increased capability for higher currents can for example be used to allow back contact cells with longer fingers (on larger substrates) than with prior art designs. Furthermore, shorter plating process times can be achieved since it will take less time to grow a given cross-section area for the electrical conductor.

Moreover, back contacted solar cells can be made with smaller metal-silicon interface area, which contributes to increased cell efficiency due to less recombination at the metal/Si interface.

Additionally, the production sequence in the embodiments above has the potential to reduce production cost for plated back contacted solar cells.

Please note that the drawings are illustrations and that the scale is not necessarily correct. In some embodiments, the passivation layer 2 is for example only about 50-100 nm whereas the thickness of the plated contacts over area A and B may be in the micrometer range. Note that these values are not meant to be limiting for the present application, it would be possible to achieve the invention with large deviations from these values.

Besides, the top section of the T-shaped contact, formed on top of the plating seed layer, needs to form a continuous current conductor, while the bottom part formed on top of the opened areas B can be non-continuous. By for example opening areas B as multiple dots after each other as a dotted line, one will obtain the generally known benefit of a local contact.

1-20. (canceled)

21. Method for providing a contact on the back surface of a solar cell, wherein the method comprises the following steps:
a) adding a passivation layer over the back surface of the silicon substrate;
b) adding a plating seed layer over the passivation layer;
c) separating the plating seed layer by a first area into first and second electrode areas;
d) opening a second area of the plating seed layer;
e) opening the second area of the passivation layer;
f) applying a contact plating to the opening of the second area of the passivation layer as well as to the plating seed layer surrounding the second area.

22. Method according to claim 21 wherein the step c) of separating the plating seed layer by a first area into first and second electrode areas comprises opening said area of the plating seed layer.

23. Method according to claim 21 wherein the step c) of separating the plating seed layer by a first area into first and second electrode areas comprises applying an insulating material on the plating seed layer.

24. Method according to claim 21, wherein both the first and second electrode areas have the same polarity.

25. Method according to claim 21, wherein that steps c) and d) are performed simultaneously.

26. Method according to claim 21, wherein step e) is performed before step b).

27. Method according to claim 21, wherein step b) is performed after step e).

28. Method according to claim 21, wherein step e) is performed by applying an etch-resistant agent to the solar cell in areas except from the second area and thereafter a applying an etching agent to etch the passivation layer open in the second area.

29. Method according to claim 21, wherein at least one of the steps c), d) or e) comprises applying an etching agent directly to the second area.

30. Method according to claim 21, wherein at least one of the steps c), d) or e) comprises a laser ablation process.

31. Method according to claim 22, wherein step c) is performed by applying an etch-resistant agent to the solar cell in areas except from the first area and thereafter applying an etching agent to etch the plating seed layer open in the first area.

32. Method according to claim 23, wherein step c) comprises depositing a plating resist layer to the solar cell at the first area.

33. Method according to claim 32, wherein the plating resist layer comprises a reflective material.

34. Method according to claim 21, characterized in that the contact plating has a substantially T-shaped cross sectional form.

35. Method according to claim 21, wherein the opened areas (B) are non-continuous while the seed layers forms continuous conducting lines.

36. Solar cell, comprising a back surface, the back surface comprising a contact, wherein the contact is provided on the back surface of the solar cell by a method as set forth in claim 21.

37. Method according to claim 22, wherein both the first and second electrode areas have the same polarity.

38. Method according to claim 23, wherein both the first and second electrode areas have the same polarity.

39. Method according to claim 22, wherein steps c) and d) are performed simultaneously.

40. Method according to claim 23, wherein steps c) and d) are performed simultaneously.
